(19) United States
(12) Patent Application Publication
(10) Pub. No.: US 2016/0027890 A1
(43) Pub. Date: Jan. 28, 2016

(54) ELECTROCHEMICALLY-GATED FIELD-EFFECT TRANSISTOR AND METHOD FOR ITS MANUFACTURE

(71) Applicant: KARLSRUHER INSTITUT FÜR TECHNOLOGIE, Karlsruhe (DE)

(72) Inventors: Horst Hahn, Seeheim-Jugenheim (DE); Subho Dasgupta, Eggenstein-Leopoldshafen (DE)

(21) Appl. No.: 14/774,724

(22) PCT Filed: Mar. 8, 2014
(86) PCT No.: PCT/EP2014/000593

§ 371 Date: Sep. 11, 2015

(30) Foreign Application Priority Data
Mar. 14, 2013 (EP) 13401025.5

(51) Int. Cl. H01L 29/49; H01L 21/02; H01L 29/66; H01L 29/786; H01L 29/06

(52) U.S. Cl. CPC H01L 29/4908; H01L 29/78642; H01L 29/0665; H01L 29/66666; H01L 29/66742; H01L 21/02288

(57) ABSTRACT

An electromechanically-gated field-effect transistor includes an arrangement which is placed on top of a substrate. The arrangement includes a first electrode, a second electrode, a transistor channel, an electrolyte, and a gate electrode. The first electrode is placed on top of the substrate and including a first solid or porous metallic conducting body, a second electrode. The second electrode is placed on top of a transistor channel so as to at least partially cover the transistor channel. The transistor channel, which includes a porous semiconducting material, is placed on top of the first electrode so as to at least partially cover the first electrode and located between the first electrode and the second electrode in a manner to prevent any direct electrical contact between the first electrode and the second electrode.

### CROSS REFERENCE TO RELATED APPLICATIONS

This application is a U.S. National Stage Application under 35 U.S.C. §371 of International Application No. PCT/EP2014/000593 filed on Mar. 8, 2014, and claims benefit to European Patent Application No. EP 13401025.5 filed on Mar. 14, 2013. The International Application was published in English on Sep. 18, 2014 as WO 2014/139652 A1 under PCT Article 21(2).

### FIELD

The present invention relates to an electrochemically-gated field-effect transistor (FET), to a method for its manufacture, to its use, and to electronics comprising said field-effect transistor.

### BACKGROUND

Printed or solution-processed electronics is a rapidly developing field for inexpensive and large-area electronics on flexible as well as rigid substrates. Printed logics encompass an important and large fraction of this activity. Worldwide there are huge and diverse efforts in search of appropriate organic or inorganic materials which are suitable for printed metallic, semiconducting, or dielectric layers in such electronic elements in order to improve the performance of devices, especially of field-effect transistors (FETs).

FETs are one of the most complex and hence widely studied electronic devices necessary to build logics. Solution-processed or printed components, which include metallic, semiconducting, and dielectric materials have been extensively studied and tested in order to optimize and improve the performance of this device. The semiconductor, which constitutes as channel material the active element of an FET, has been explored most extensively. Organic and low or high temperature process-able inorganic semiconductors which are solution-processed or printed have been proposed and examined. Within this development, substantially good static electrical characteristics of FETs have already been achieved whereas the dynamic performance, i.e., the switching speed of the FETs, is still a major issue which is retarding their application in practice.

Since the field-effect mobility μ_{FET} is proportional to the switching frequency f_{T}, much effort has been made to improve the μ_{FET} of semiconductors in order to acquire a higher f_{T}. Although large improvements in the μ_{FET} of organic semiconductors have been achieved during the last decade, μ_{FET} hardly exceeds 1 cm²/Vs, whereas inorganic semiconductors have shown slightly higher values. Nevertheless, these values are already comparable to amorphous silicon; however, the problem of the switching speed still persists in printed logics due to Equation (1):

$$f ∞ \frac{{μ}_{FET}}{{L}^{2}} \qquad ( 1 )$$

According to Eq. (1), f_{T} is inversely proportional to the square of the channel length L of the FET. Within this respect it is important to acknowledge that the channel length L of a printed device is usually rather large due to a limited printing resolution. A channel length L between 20-30 μm is the minimum which can be achieved by using a modern-day printer.

This value for the channel length L is much larger compared to values known from silicon electronics where the channel length L is lithographically determined to only a few tens of nanometres and thus drastically affects the switching speed of printed FETs.

Electrochemically-gated FETs in which inorganic oxides are employed as the transistor channel are described in WO 2012/025190 A1 as well as in refs. [1, 2].

In order to solve this issue with the limited resolution which a printer can offer, a new approach called ‘self-aligned printing’ which is described in refs. [3-5] was introduced. Here, a first metallic electrode is placed onto a substrate and a selective modification of the surface of this electrode along with a change in surface energy is carried out by evaporating a self-assembled monolayer of an organic species onto it. When a second electrode is placed or printed on top of the first electrode, it dislikes the first electrode surface and flows off until it is completely separated aside from the first electrode. In this manner, a channel of a few hundreds of nanometers could be obtained. Electrochemical gating is known from ref [6].

### SUMMARY

In an embodiment, the present invention provides an electrochemically-gated field-effect transistor, comprising an arrangement disposed on top of a substrate. The arrangement comprises a first electrode, the first electrode being disposed on top of the substrate and including a first solid or porous metallic conducting body; a second electrode including a second solid or porous metallic conducting body; a transistor channel, which comprises a porous semiconducting material, and which is disposed on top of the first electrode so as to at least partially cover the first electrode, and which is located between the first electrode and the second electrode in a manner to prevent any direct electrical contact between the first electrode and the second electrode; an electrolyte, which covers the transistor channel completely, which penetrates at least through the transistor channel while leaving a part of the first electrode and a part of the second electrode uncovered; and a gate electrode, which comprises a third solid or porous metallic conducting body and is placed in direct contact with the electrolyte but without any direct physical contact to the arrangement wherein the second electrode is disposed on top of the transistor channel so as to at least partially cover the transistor channel.

### BRIEF DESCRIPTION OF THE DRAWINGS

The present invention will be described in even greater detail below based on the exemplary figures. The invention is not limited to the exemplary embodiments. All features described and/or illustrated herein can be used alone or combined in different combinations in embodiments of the invention. The features and advantages of various embodiments of the present invention will become apparent by reading the following detailed description with reference to the attached drawings which illustrate the following:

FIG. 1 shows a side/cross-sectional view of an FET according to an embodiment of the invention where a gate is placed on top of other layers (top gate);

FIG. 2 displays a top view of the FET of FIG. 1;

FIG. 3 exhibits a side/cross-sectional view of an FET according to an embodiment of the invention where a gate is placed at the side of other layers (side gate or displaced gate); and

FIG. 4 displays a top view of the FET of FIG. 3.

### DETAILED DESCRIPTION

Self-aligned printing can be slow and tedious, and surface modification of one of the electrodes reduces the performance of FETs. An embodiment of the present invention provides an electrochemically-gated field-effect transistor (FET), a method for its manufacture, and printed electronics comprising the electrochemically-gated FET, which address the limitations known from the state of the art.

In an embodiment, the present invention provides an electrochemically-gated FET where the channel length L is independent from the printing resolution, and as a result, is much thinner and much shorter compared to the printing resolution.

In an embodiment, the present invention provides a method for manufacturing an electrochemically-gated FET through a completely solution-processed or printing route.

In an embodiment, the present invention provides flexible and/or bendable and/or transparent and/or printed electronics which applies an electrochemically-gated FET.

In an embodiment, the present invention provides to an electrochemically-gated FET, which employs an arrangement which is placed on top of a substrate and which includes a first electrode, which is either a source electrode or a drain electrode, and a second electrode, which, if the first electrode is a source electrode, is a drain electrode, or, if the first electrode is a drain electrode, is a source electrode. The arrangement additionally includes a transistor channel, which is located between the first electrode and the second electrode and prevents any direct electrical contact between the first electrode and the second electrode an electrolyte which is used as gate dielectric and which covers the transistor channel completely, and a gate electrode.

In an embodiment, the first electrode employs a first solid or porous metallic conducting body and is placed on top of the substrate.

In an embodiment, the transistor channel employs a porous semiconducting material and is placed on top of the first electrode by which it partially covers the first electrode, thereby leaving some uncovered area suitable for contacting the first electrode with electrical contacts available from outside the device. In a preferred embodiment, the transistor channel is partially placed on the substrate. In a particularly preferred embodiment, the transistor channel employs an organic or an inorganic or a carbon based nanomaterial, preferably organic or inorganic or carbon based nanoparticles, nanowires, nanorods, nanowhiskers, nanoflakes, nanofibres, or nanotubes, preferentially inorganic oxide nanoparticles.

In an embodiment, the second electrode is placed partially on top of the transistor channel, which is itself arranged on top of the first electrode, which is itself positioned on top of the substrate. It is important that the second electrode at least partially covers the transistor channel but exhibits no direct physical contact to the first electrode in order to avoid any electric short circuit. In a preferred embodiment, the second electrode has a direct physical contact with the substrate.

In an embodiment, the second electrode employs a second solid or porous metallic conducting body. Preferentially, the second electrode is porous in order to allow an easy penetration of the electrolyte from above through its body down to the porous semiconducting transistor channel layer. In a specific embodiment, however, the second electrode is a solid and does not possess any pores, in which case the electrolyte will suck only into the pores of the transistor channel layer directly from all available sides due to any capillary forces.

In an embodiment, the electrolyte which acts as a dielectric penetrates through the transistor channel and may penetrate through the second electrode while leaving a part of the first electrode and a part of the second electrode uncovered. The latter feature is required in order to ensure that the electrical contact available from outside the device to the first electrode as well as to the second electrode is achieved without directly contacting the electrolyte.

It is important to make sure that the complete transistor channel, which is sandwiched between the first electrode and the second electrode, must come into close, tight and inherent contact to the electrolyte. This is required for an accumulation of charge everywhere in the channel sandwiched between the source and the drain electrode and ensures that the transistor is in the situation to achieve an ON state. It is important to note that in case the electrolyte does not penetrate through the transistor channel all the way down to the first electrode, the device will not work properly since within the semiconducting transistor channel a layer will remain which does not show charge-carrier accumulation as long as no electrolyte has reached it.

Finally, in an embodiment, the gate electrode comprises a third solid or porous metallic conducting body. It is placed in direct contact with the electrolyte but avoids any direct physical contact to any parts of the arrangement.

In a preferred embodiment, also called top gate, the gate electrode is placed on top of the arrangement, which consist of the first electrode, the second electrode, the transistor channel in between and the electrolyte covering or penetrating through any of these layers.

In an alternatively preferred embodiment, also called side gate or displaced gate, the gate electrode is placed on top of the substrate but aside from said arrangement.

An FET arranged according to the present invention defines the thickness of the porous semiconducting transistor channel as the channel length L, which is independent of the printing resolution and, in particular, can be much thinner and shorter than the printing resolution. Depending on the primary particle size of the nanomaterial in the transistor channel, the channel length L is smaller than 1 μm, particularly smaller than 100 nm, preferentially smaller than 10 nm.

In addition, there is a further difference in the transistor geometry according to this invention compared to the usual geometry where both the source electrode and the drain electrode are placed on the same substrate. In the present geometry, not only the width W of the channel but also the spread B of the channel is important. Depending on the thickness of the semiconductor layer which defines the channel length L and the width×spread W·B of the transistor channel, which is defined as the common overlap area of the channel with both the source electrode and the drain electrode, a much larger current is able to pass through the transistor channel when the device is at the ON state. On the other hand, an initially low intrinsic carrier density in the semiconductor, which is defined by the carrier density at the unbiased state, i.e. at zero gate bias, would be essential to keep the OFF currents to a low value.

In an embodiment, the present invention further provides a method of manufacturing an electrochemically-gated FET. According to the embodiment of the present invention, the following steps (a) to (e) are employed:

First, according to step (a), a first metallic conducting body, which is either solid or porous in nature, is placed on top of a substrate to be used as a first electrode.

Then, according to step (b), a porous semiconducting material which is provided to work as the active element of the FET, i.e. the transistor channel, is placed on top of the first electrode in a manner that it partially covers the first electrode and leaves some area uncovered for contacting the first electrode with outside contacts. In a specific embodiment, the second electrode is partially placed on the substrate. In particular, the porous semiconducting material is selected from an organic or an inorganic or a carbon based nanomaterial, preferably from organic or inorganic nanoparticles, nanowires, nanorods, nanowhiskers, nanoflakes, nanofibres, or nanotubes, preferentially from inorganic oxide nanoparticles.

Next, according to step (c), a second solid or porous metallic conducting body is placed as second electrode on top of the transistor channel, which is placed on top of the first electrode. The placing is performed in a manner that the second electrode at least partially covers the transistor channel but does not directly contact the first electrode. In a specific embodiment, the transistor channel is partially placed on the substrate. By this step, an arrangement is obtained, which consists of the first electrode, of the second electrode, and of the transistor channel located between the first electrode and the second electrode.

Thereafter, according to step (d), an electrolyte which acts as a dielectric is applied on top of the arrangement in a manner that the electrolyte penetrates the transistor channel completely and may penetrate through the second electrode, while leaving a part of the first electrode and of the second electrode, respectively, uncovered.

In a preferred embodiment, the electrolyte is applied during step (d) in a manner that it penetrates at least through the transistor channel to reach up to the first electrode.

In an alternatively preferred embodiment, the electrolyte is applied during step (d) in a manner that it gets sucked into the transistor channel from all available sides. This embodiment is of particular importance when the second electrode is chosen from a solid body and does not possess any pores.

Finally, according to step (e), a third solid or porous metallic conducting body is placed to work as gate electrode in a manner that it is in direct physical contact with the electrolyte while no direct physical contact to the arrangement is obtained.

In a preferred embodiment, the gate electrode is placed during step (e) directly on top of the arrangement (top gate).

In another preferred embodiment, the gate electrode is placed during step (e) on top of the substrate but aside from the arrangement (side gate or displaced gate).

In a preferred embodiment, the placing of the first metallic conducting body and/or the placing of the second metallic conducting body and/or the placing of the third metallic conducting body and/or the placing of the porous semiconducting material and/or the applying of the electrolyte is performed by solution processing or by a printing technique which is based preferably on solution processing.

The present invention further relates to printed electronics which comprises an electrochemically-gated field-effect transistor as described on any kind of flexible substrate, including paper or polymer. The obtained devices can be highly flexible or bendable since the metallic bodies, the semiconducting channels and the solid polymer-based electrolyte may be capable of enduring high strain.

The present invention shows a wide field of applications in high-performance transistors or logics or circuitry involving porous transistor channel and electrochemical-gating with solution-processable and/or printable solid polymer-based electrolytes. In addition, the present invention opens a way for use of FETs in applications involving partially or completely solution-processed and/or partially or completely printed electronic devices, transistors, logics, circuitry which involves such a device. Further, applications of the aforementioned device in the field of flexible and/or bendable and/or transparent and/or portable electronics and/or displays, smart packaging, smart toys, smart textiles, etc. are possible.

The main advantage of the FET geometry presented in embodiments herein is that all elements of the FET can be printed, whereby the channel length L is no longer limited by the printing resolution. Thus, the channel length L can be very small, e.g., down to a few nanometres.

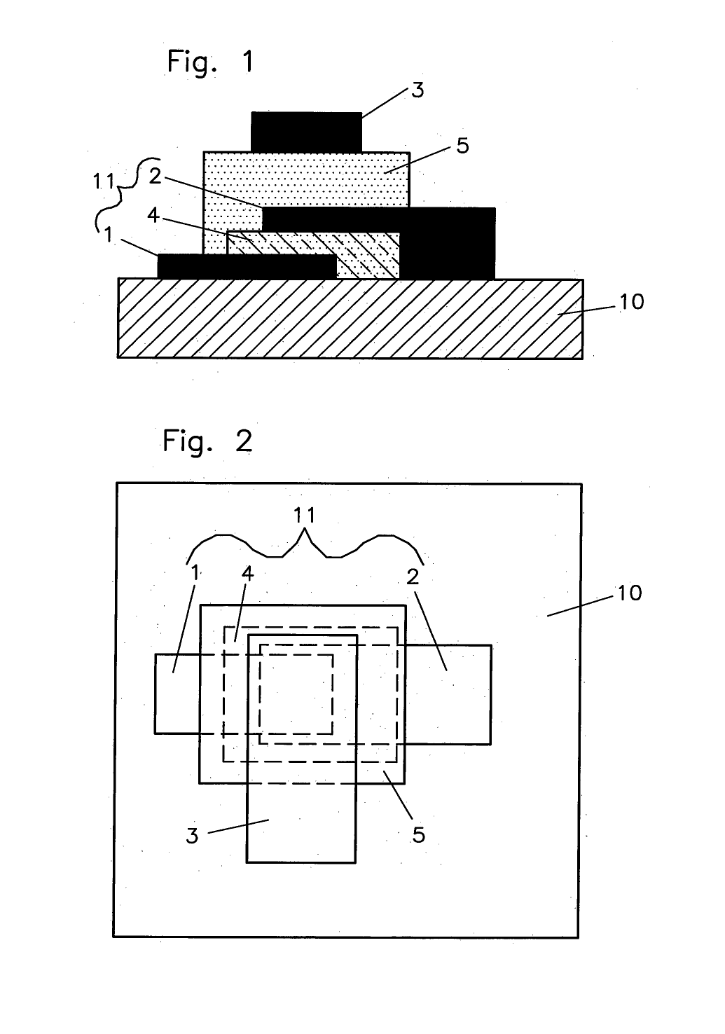

The manufacturing of an FET according to the present invention is fully compatible to an all-solution processed and all-printed synthesis. Referring to FIGS. 1-4, the manufacturing of the device starts with a first metallic conducting body which is placed or positioned as first electrode 1, as an example also called source electrode, onto the substrate 10, preferably by a solution based technique, more preferably by a printing technique. The metallic conducting body is either solid and non-porous or porous in nature.

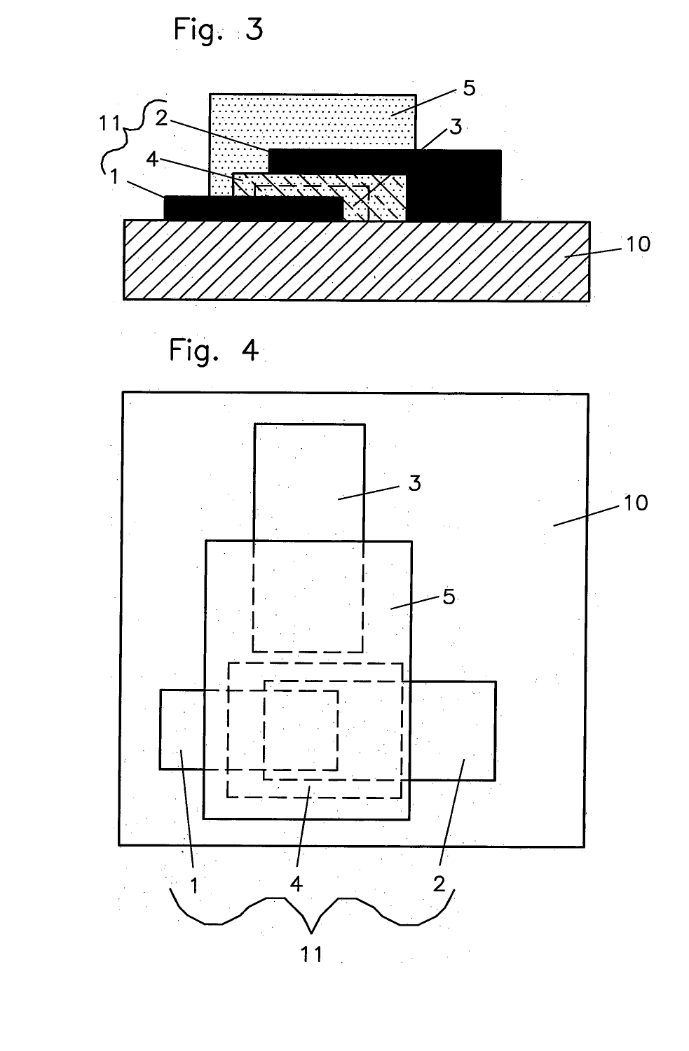

Next, the active element of the transistor, i.e., the semiconducting transistor channel 4 is placed or deposited on top of the first electrode 1 in a manner that it according to FIGS. 1 and 3 partially covers the source electrode 1, thereby leaving some area uncovered for contacting the source electrode 1, and may partially be placed onto the substrate 10. The semiconducting material is preferentially placed by solution processing, more preferentially by printing techniques. The semiconducting channel layer must be porous in nature, preferentially provided by inorganic oxide nanoparticles.

Then, a second metallic conducting body is placed or positioned preferably by any solution based techniques, more preferably by printing techniques as second electrode 2, as example also called drain electrode, on top of the first electrode 1 and on top of the semiconducting channel 4 in a manner that it at least partially covers the semiconducting channel 4 but has no direct physical contact to the first electrode 1. In this example it shows direct physical contact with the substrate 10. Preferentially, the second electrode 2 is porous in order to allow an easy penetration of the electrolyte 5 through the porous semiconducting transistor channel layer 4, down to the first electrode 1. Alternatively, the second electrode 2 is solid in which case the electrolyte 5 will suck into the pores of the semiconducting transistor channel layer 4 from all available sides due to any capillary forces.

Next, an electrolyte 5 which acts a dielectric is applied on top of this three layer stack, i.e. an arrangement 11 of two body electrodes 1, 2 and the transistor channel 4 sandwiched between them, in a manner that it either penetrates through the second electrode 2 and also penetrates the transistor channel 4 to reach up to the source electrode or gets sucked into the transistor channel 4 from all available sides in case the second electrode 2 is solid and non-porous. In both kinds of conditions, the complete semiconducting transistor channel layer 4 which is sandwiched between body electrodes 1 and 2 must come into contact to the electrolyte 5 for an accumulation of charge and to ensure that the transistor may achieve an ON state. The electrolyte 5 which is preferentially applied or placed or positioned or deposited by solution casting or more preferentially by printing must leave a part of the source and drain electrodes uncovered, as shown in FIGS. 1-4, to allow electrical contacts to the body electrodes 1, 2 without contacting the electrolyte 5.

Finally, a third metallic conducting electrode which is solid and non-porous or porous in nature is placed or positioned as gate electrode 3 which keeps contact with the electrolyte 5 in a manner that it is, as shown in FIGS. 1-2, either placed directly on top of the arrangement 11, or placed, as shown in FIGS. 3-4, at the side of the arrangement 11. The gate electrode 5 is placed or positioned preferably by a solution-based technique, more preferably by a printing technique, in a manner that it exhibits only a contact to the electrolyte 5 and no electrical contact neither to the source electrode 1, the drain electrode 2, nor the semiconducting channel 4, i.e. any part of the arrangement 11.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LITERATURE

[1] S. Dasgupta, G. Stoesser, N. Schweikert, R. Hahn, S. Dehm, R. Kruk, H. Hahn, Adv. Funct. Mater., 22 (2012) 4909-4919
[2] S. Dasgupta, R. Kruk, N. Mechau, H. Hahn, ACS Nano 5 (2011) 9628
[3] Y.-Y. Noh, N. Zhao, M. Caironi, H. Sirringhaus, Nature Nanotechnology 2 (2007) 784-789
[4] C. W. Sele, T. vonWerne, R. H. Friend, H. Sirringhaus, Adv. Mater., 17 (2005) 997-1001
[5] L. Herlogsson, Y.-Y. Noh, N. Zhao, X. Crispin, H. Sirringhaus, M. Berggren, Adv. Mater. 20 (2008) 4708-4713
[6] S. H. Kim, K. Hong, W. Xie, K. H. Lee, S. Zhang, T. P. Lodge, C. D. Frisbie, Adv. Mater. 2012, DOI: 10.1002/adma.201202790

1. An electrochemically-gated field-effect transistor, comprising:
an arrangement disposed on top of a substrate and which comprises:
a first electrode, the first electrode being disposed on top of the substrate and including a first solid or porous metallic conducting body;
a second electrode including a second solid or porous metallic conducting body;
a transistor channel, which comprises a porous semiconducting material, and which is disposed on top of the first electrode so as to at least partially cover the first electrode, and which is located between the first electrode and the second electrode in a manner to prevent any direct electrical contact between the first electrode and the second electrode;
an electrolyte, which covers the transistor channel completely, which penetrates at least through the transistor channel while leaving a part of the first electrode and a part of the second electrode uncovered; and
a gate electrode,
which comprises a third solid or porous metallic conducting body and is disposed in direct contact with the electrolyte but without any direct physical contact to the arrangement wherein the second electrode is disposed on top of the transistor channel so as to at least partially cover the transistor channel.

2. The electrochemically-gated field-effect transistor according to claim 1, wherein the gate electrode is disposed on top of the arrangement.

3. The electrochemically-gated field-effect transistor according to claim 1, wherein the gate electrode is disposed on top of the substrate but aside from the arrangement.

4. The electrochemically-gated field-effect transistor according to claim 1, wherein the transistor channel comprises at least one of a carbon based nanomaterial, an organic nanomaterial, or an inorganic nanomaterial.

5. The electrochemically-gated field-effect transistor according to claim 4, wherein the transistor channel comprises at least one of organic or inorganic or carbon based nanoparticles, nanowires, nanorods, nanowhiskers, nanoflakes, nanofibres, or nanotubes.

6. A method of manufacturing an electrochemically-gated field-effect transistor the method comprising the following steps:
disposing a first solid or porous metallic conducting body on top of a substrate as a first electrode;
disposing a porous semiconducting material as a transistor channel on top of the first electrode so as to partially covers the first electrode;
disposing a second solid or porous metallic conducting body on top of the transistor channel as a second electrode so as to at least partially covers the transistor channel and to prevent any direct electrical contact to the first electrode, by which an arrangement, which includes the first electrode, the transistor channel, and the second electrode, is obtained;
applying an electrolyte on top of the arrangement in a manner that the electrolyte penetrates at least through the transistor channel completely down to the first electrode; and
disposing a third solid or porous metallic conducting body as a gate electrode in direct contact with the electrolyte in a manner that no direct physical contact to the arrangement is achieved.

7. The method according to claim 6, wherein the applying the electrolyte on top of the arrangement in a manner that the electrolyte penetrates at least through the transistor channel completely down to the first electrode comprises:
applying the electrolyte in a manner such that the electrolyte is sucked into the transistor channel from sides thereof.

8. The method according to claim 6, wherein the disposing a second solid or porous metallic conducting body on top of the transistor channel as a second electrode so as to at least partially cover the transistor channel and to prevent any direct electrical contact to the first electrode comprises selecting a second porous metallic conducting body as the second electrode; and
wherein the applying an electrolyte on top of the arrangement in a manner that the electrolyte penetrates at least through the transistor channel completely down to the first electrode comprises applying the electrolyte in a manner that it also penetrates at least partially through the second electrode.

9. The method according to claim 6, wherein the disposing a third solid or porous metallic conducting body as a gate electrode in direct contact with the electrolyte in a manner that no direct physical contact to the arrangement is achieved comprises disposing the gate electrode directly on top of the arrangement.

10. The method according to claim 6, wherein the disposing a third solid or porous metallic conducting body as a gate electrode in direct contact with the electrolyte in a manner that no direct physical contact to the arrangement is achieved comprises disposing the gate electrode on top of the substrate but aside from the arrangement.

11. The method according to claim 6, wherein at least one of the disposing the first metallic conducting body, the disposing the second metallic conducting body, the disposing the third metallic conducting body, the disposing the porous semiconducting material, or applying the electrolyte is performed by a solution-processing method.

12. The method according to claim 6, wherein at least one of the disposing the first metallic conducting body, the disposing the second metallic conducting body, the disposing the third metallic conducting body, the disposing the porous semiconducting material, or applying the electrolyte is performed by a printing method.

13. The method according to claim 6, wherein the porous semiconducting material comprises at least one of a carbon based nanomaterial, an organic nanomaterial, or an in-organic nanomaterial.

14. (canceled)

15. An electronic system, comprising:
an electrochemically-gated field-effect transistor, comprising:
an arrangement disposed on top of a substrate and which comprises:
a first electrode, the first electrode being disposed on top of the substrate and including a first solid or porous metallic conducting body;
a second electrode including a second solid or porous metallic conducting body;
a transistor channel, which comprises a porous semiconducting material, and which is disposed on top of the first electrode so as to at least partially cover the first electrode, and which is located between the first electrode and the second electrode in a manner to prevent any direct electrical contact between the first electrode and the second electrode;
an electrolyte, which covers the transistor channel completely, which penetrates at least through the transistor channel while leaving a part of the first electrode and a part of the second electrode uncovered; and
a gate electrode, which comprises a third solid or porous metallic conducting body and is placed in direct contact with the electrolyte but without any direct physical contact to the arrangement wherein the second electrode is disposed on top of the transistor channel so as to at least partially cover the transistor channel.
